(19) United States
(12) Patent Application Publication
(10) Pub. No.: US 2024/0339303 A1
(43) Pub. Date: Oct. 10, 2024

(54) SUBSTRATE SUPPORT AND PLASMA PROCESSING APPARATUS

(71) Applicant: Tokyo Electron Limited, Tokyo (JP)

(72) Inventors: Shin YAMAGUCHI, Miyagi (JP); Daiki SATOH, Miyagi (JP); Takashi KANAZAWA, Miyagi (JP); Makoto KATO, Miyagi (JP)

(73) Assignee: Tokyo Electron Limited, Tokyo (JP)

(21) Appl. No.: 18/749,678

(22) Filed: Jun. 21, 2024

Related U.S. Application Data
(63) Continuation of application No. PCT/JP2022/045489, filed on Dec. 9, 2022.

(30) Foreign Application Priority Data
Dec. 23, 2021 (JP) 2021-209202

(51) Int. Cl. H01J 37/32

(52) U.S. Cl. CPC H01J 37/32568; H01J 37/32642; H01J 37/32715; H01J 2237/2007

(57) ABSTRACT

A substrate support comprises an electrostatic chuck configured to support a substrate and an edge ring and a base configured to support the electrostatic chuck. The electrostatic chuck includes a first region having a first upper surface and configured to support a substrate placed on the first upper surface, a second region having a second upper surface and configured to support an edge ring placed on the second upper surface, a first electrode disposed in the first region and to which a DC voltage is applied, a second electrode disposed below the first electrode and to which a first bias power is supplied, a third electrode disposed below the second electrode and to which the first bias power is supplied and a first gas supply line disposed between the second electrode and the third electrode.

### CROSS-REFERENCE TO RELATED APPLICATIONS

This application is a bypass continuation application of International Application No. PCT/JP2022/045489 having an international filing date of Dec. 9, 2022, and designating the United States, the International Application being based upon and claiming the benefit of priority from Japanese Patent Application No. 2021-209202 filed on Dec. 23, 2021, the entire contents of each are incorporated herein by reference.

### TECHNICAL FIELD

The present disclosure relates to a substrate support and a plasma processing apparatus.

### BACKGROUND

Japanese Laid-open Patent Publication No. 2020-205379 discloses a placing table provided with an electrostatic chuck for supporting a substrate and an edge ring. The electrostatic chuck disclosed in Japanese Laid-open Patent Publication No. 2020-205379 has an attracting electrode. When a DC voltage is applied to the attracting electrode, an electrostatic attractive force is generated, and a substrate is held by the electrostatic attractive force. Further, the electrostatic chuck has a bias electrode to which a bias power for ion attraction is applied.

### SUMMARY

The technique of the present disclosure suppresses occurrence of abnormal discharge in a substrate support having an electrostatic chuck and a heat transfer gas channel.

One aspect of present disclosure provides a substrate support comprising: an electrostatic chuck configured to support a substrate and an edge ring; and a base configured to support the electrostatic chuck, wherein the electrostatic chuck includes: a first region having a first upper surface and configured to support a substrate placed on the first upper surface; a second region having a second upper surface, disposed around the first region, and configured to support an edge ring placed on the second upper surface; a first electrode disposed in the first region and to which a DC voltage is applied; a second electrode disposed below the first electrode and to which a first bias power is supplied; a third electrode disposed below the second electrode and to which the first bias power is supplied; and a first gas supply line disposed between the second electrode and the third electrode, wherein the substrate support further comprises: a first power supply line that is in electrical contact with the second electrode and the third electrode and supplies the first bias power.

### BRIEF DESCRIPTION OF THE DRAWINGS

FIG. 1 is a diagram for explaining a configuration example of a plasma processing system.

FIG. 2 is a diagram for explaining a configuration example of a capacitively coupled plasma processing apparatus.

FIG. 3 is a cross-sectional view schematically showing a configuration example of a substrate support.

FIG. 4 is a diagram showing positional relationship between a fifth electrode and a second via.

FIG. 5 is a diagram showing positional relationship between a sixth electrode and a third via.

FIG. 6 is a diagram showing another example of a first internal power supply line.

FIG. 7 is a diagram showing another example of a first power supply terminal.

FIG. 8 is a diagram showing a specific example of positional relationship between a third electrode and a fifth electrode.

### DETAILED DESCRIPTION

In a manufacturing process of semiconductor devices and the like, plasma processing such as etching and film formation is performed on a substrate such as a semiconductor wafer (hereinafter referred to as “wafer”) using plasma. The plasma processing is performed in a state where the substrate is held by an electrostatic chuck of a substrate support by an electrostatic force.

Since the temperature of the substrate affects the results of plasma processing, the substrate support is provided with a temperature control mechanism for adjusting the temperature of the electrostatic chuck, or a channel for supplying a heat transfer gas to a gap between a substrate placing surface of an electrostatic chuck and the backside of the substrate.

However, when the substrate support is provided with the heat transfer gas channel, abnormal discharge may occur in the channel.

Further, in order to improve a processing speed such as an etching rate, a bias electrode for ion attraction, i.e., for bias, is disposed in the electrostatic chuck.

Although abnormal discharge can be suppressed by providing a bias electrode in addition to the heat transfer gas channel, further improvement can be made.

Therefore, the technique of the present disclosure further suppresses the occurrence of abnormal discharge in a substrate support having an electrostatic chuck and a heat transfer gas channel.

Hereinafter, a substrate support and a plasma processing apparatus according to the present embodiment will be described with reference to the accompanying drawings. Further, like reference numerals will be used for like parts having substantially the same functions and configurations throughout this specification and the drawings, and redundant description thereof will be omitted.

### Plasma Processing System

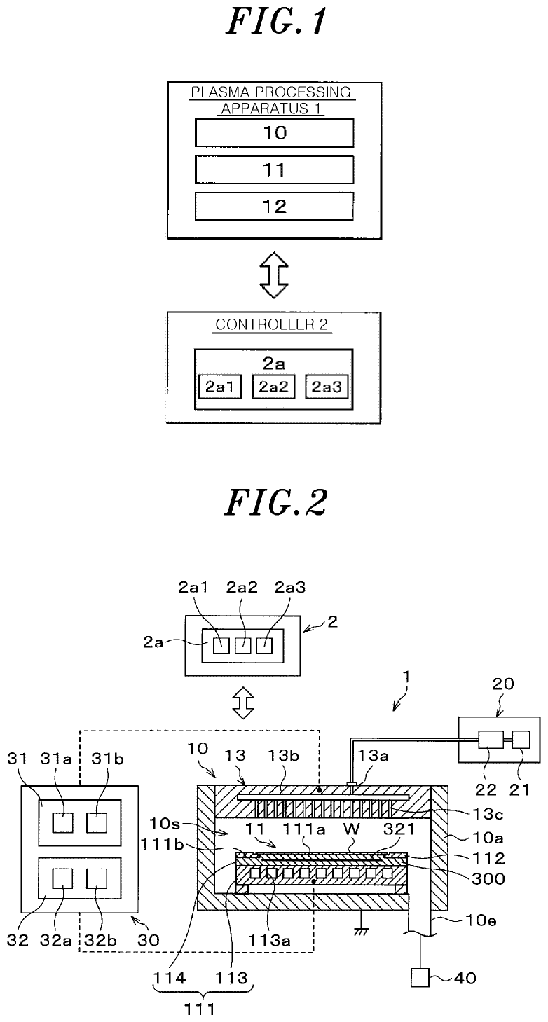

First, a plasma processing system including a plasma processing apparatus according to an embodiment will be described with reference to FIG. 1. FIG. 1 is a diagram for explaining a configuration example of the plasma processing system.

In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas to the plasma processing space, and at least one gas exhaust port for discharging a gas from the plasma processing space. The gas supply port is connected to a gas supply part 20 to be described later, and the gas exhaust port is connected to an exhaust system 40 to be described later. The substrate support 11 is disposed in the plasma processing space, and has a substrate supporting surface for supporting a substrate.

The plasma generator 12 is configured to generate plasma from at least one processing gas supplied into the plasma processing space. The plasmas generated in the plasma processing space may be capacitively coupled plasma (CCP), inductively coupled plasma (ICP), and electron-cyclotron-resonant plasma (ECR), helicon wave plasma (HWP), surface wave plasma (SWP), or the like. Further, various types of plasma generator, such as an alternating current (AC) plasma generator and a direct current (DC) plasma generator, may be used. In one embodiment, an AC signal (AC power) used in the AC plasma generator has a frequency within a range of 100 kHz to 10 GHZ. Therefore, the AC signal includes a radio frequency (RF) signal and a microwave signal. In one embodiment, the RF signal has a frequency within a range of 100 kHz to 150 MHz.

The controller 2 processes computer-executable instructions that cause the plasma processing apparatus 1 to perform various steps described in the present disclosure. The controller 2 may be configured to control individual elements of the plasma processing apparatus 1 to perform various steps described herein. In one embodiment, the controller 2 may be partially or entirely included in the plasma processing apparatus 1. The controller 2 may include a processing part 2a1, a storage part 2a2, and a communication interface 2a3. The controller 2 is realized by, e.g., a computer 2a. The processing part 2a1 may be configured to read a program from the storage part 2a2, and perform various control operations by executing the read program. The program may be stored in advance in the storage part 2a2, or may be acquired via a medium when necessary. The acquired program is stored in the storage part 2a2, and is read out from the storage part 2a2 and executed by the processing part 2a1. The medium may be various storage media readable by the computer 2a, or may be a communication line connected to the communication interface 2a3. The processing part 2a1 may be a central processing unit (CPU). The storage part 2a2 includes a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN) or the like.

### Plasma Processing Apparatus

Hereinafter, a configuration example of a capacitively coupled plasma processing apparatus as an example of the plasma processing apparatus 1 will be described. FIG. 2 is a diagram for explaining a configuration example of the capacitively coupled plasma processing apparatus.

The capacitively coupled plasma processing apparatus 1 includes the plasma processing chamber 10, the gas supply part 20, a power supply 30, and an exhaust system 40. Further, the plasma processing apparatus 1 includes a substrate support 11 and a gas introducing part. The gas introducing part is configured to introduce at least one processing gas into the plasma processing chamber 10. The gas introducing part includes a shower head 13. The substrate support 11 is disposed in the plasma processing chamber 10. The shower head 13 is disposed above the substrate support 11. In one embodiment, the shower head 13 forms at least a part of the ceiling of plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting the substrate W and an annular region 111b for supporting the ring assembly 112. A wafer is an example of the substrate W. The annular region 111b of the main body 111 surrounds the central region 111a of the main body 111 in plan view. The substrate W is disposed on the central region 111a of the main body 111, and the ring assembly 112 is disposed on the annular region 111b of the main body 111 to surround the substrate W on the central region 111a of the main body 111. Therefore, the central region 111a is also referred to as a substrate supporting surface for supporting the substrate W, and the annular region 111b is also referred to as a ring supporting surface for supporting the ring assembly 112.

In one embodiment, the main body 111 includes a base 113 and an electrostatic chuck 114. The base 113 includes a conductive member. The conductive member of the base 113 can function as a lower electrode. The electrostatic chuck 114 is disposed on the base 113. The electrostatic chuck 114 includes a ceramic member 300 and a first electrode 321 as an electrostatic electrode disposed in the ceramic member 300. The ceramic member 300 has the central region 111a. In one embodiment, the ceramic member 300 also has the annular region 111b. Further, another member surrounding the electrostatic chuck 114, such as an annular electrostatic chuck or an annular insulating member, may have the annular region 111b. In this case, the ring assembly 112 may be disposed on the annular electrostatic chuck or the annular insulation member, or may be disposed on both the electrostatic chuck 114 and the annular insulation member. Further, a second electrode 322 (see FIG. 2 to be described later) as a bias electrode, which is connected to an RF power supply 31 and/or a DC power supply 32 to be described later and to which a bias RF signal and/or a DC signal is supplied, is disposed in the ceramic member 300. Further, at least one RF/DC electrode, which is connected to the RF power supply 31 and/or the DC power supply 32 to be described later and functions as a lower electrode, may be disposed in the ceramic member 300. Further, the conductive member of the base 113 and at least one RF/DC electrode may function as a plurality of lower electrodes. Further, the first electrode 321 as an electrostatic electrode may function as a lower electrode. Thus, the substrate support 11 includes at least one lower electrode.

The ring assembly 112 includes one or multiple annular members. In one embodiment, one or multiple annular members include one or multiple edge rings and at least one cover ring. The edge ring is made of a conductive material or an insulating material, and the cover ring is made of an insulating material.

Further, the substrate support 11 may include a temperature control module configured to adjust at least one of the electrostatic chuck 114, the ring assembly 112, and the substrate W to a target temperature. The temperature control module may include a heater, a heat transfer medium, a channel 113a, or a combination thereof. A heat transfer fluid such as brine or a gas flows through the channel 113a. In one embodiment, the channel 113a is formed in the base 113, and one or multiple heaters are disposed in the ceramic member 300 of the electrostatic chuck 114. Further, the substrate support 11 includes a heat transfer gas supply part configured to supply a heat transfer gas to the gap between the backside of the substrate W and the central region 111a.

The shower head 13 is configured to introduce at least one processing gas from the gas supply part 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the plurality of gas inlet ports 13c. Further, the shower head 13 includes at least one upper electrode. Further, the gas introducing part may include, in addition to the shower head 13, one or multiple side gas injectors (SGI) attached to one or multiple openings formed in the sidewall 10a.

The gas supply part 20 may include at least one gas source 21 and at least one flow rate controller 22. In one embodiment, the gas supply part 20 is configured to supply at least one processing gas from the corresponding gas source 21 to the shower head 13 via the corresponding flow rate controller 22. The flow rate controllers 22 may include, e.g., a mass flow controller or a pressure-controlled flow rate controller. Further, the gas supply part 20 may include at least one flow modulation device for modulates the flow rate of at least one processing gas or causing it to pulsate.

The power supply 30 includes an RF power supply 31 connected to the plasma processing chamber 10 via at least one impedance matching circuit. The RF power supply 31 is configured to supply at least one RF signal (RF power) to at least one lower electrode and/or at least one upper electrode. Accordingly, plasma is produced from at least one processing gas supplied to the plasma processing space 10s. Therefore, the RF power supply 31 can function as at least a part of the plasma generator 12. Further, by supplying a bias RF signal to the second electrode (see FIG. 2 to be described later), a bias potential is generated at the substrate W, and ion components in the produced plasma can be attracted to the substrate W.

In one embodiment, the RF power supply 31 includes a first RF generator 31a and a second RF generator 31b. The first RF generator 31a is connected to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate multiple source RF signals having different frequencies. The generated one or multiple source RF signals are provided to at least one lower electrode and/or at least one upper electrode.

The second RF generator 31b is connected to a second electrode 322 (see FIG. 2 to be described later) via at least one impedance matching circuit, and is configured to generate a bias RF signal (bias RF power). The frequency of the bias RF signal may be the same as or different from the frequency of the source RF signal. In one embodiment, the bias RF signal has a frequency lower than that of the source RF signal. In one embodiment, the bias RF signal has a frequency within a range of 100 KHz to 60 MHz. In one embodiment, the second RF generator 31b may be configured to generate multiple bias RF signals having different frequencies. The generated one or multiple bias RF signals are provided to at least one lower electrode. Further, in various embodiments, at least one of the source RF signal and the bias RF signal may pulsate.

Further, the power supply 30 may include a DC power supply 32 connected to plasma processing chamber 10. The DC power supply 32 includes a first DC generator 32a and a second DC generator 32b. In one embodiment, the first DC generator 32a is connected to at least one lower electrode, and is configured to generate a first DC signal. The generated first DC signal is applied to at least one lower electrode. In one embodiment, the second DC generator 32b is connected to the at least one upper electrode, and is configured to generate a second DC signal. The generated second DC signal is applied to the at least one upper electrode.

In various embodiments, the first and second DC signals may pulsate. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from a DC signal is connected between the first DC generator 32a and at least one lower electrode. Therefore, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. Further, the sequence of voltage pulses may include one or multiple positive voltage pulses and one or multiple negative voltage pulses in one cycle. Further, the first and second DC generators 32a and 32b may be provided in addition to the RF power supply 31, or the first DC generator 32a may be provided instead of the second RF generator 31b.

The exhaust system 40 may be connected to a gas exhaust port 10e disposed at the bottom portion of the plasma processing chamber 10, for example. The exhaust system 40 may include a pressure control valve and a vacuum pump. The pressure in the plasma processing space 10s is adjusted by the pressure control valve. The vacuum pump may include a turbomolecular pump, a dry pump, or a combination thereof.

### Substrate Support

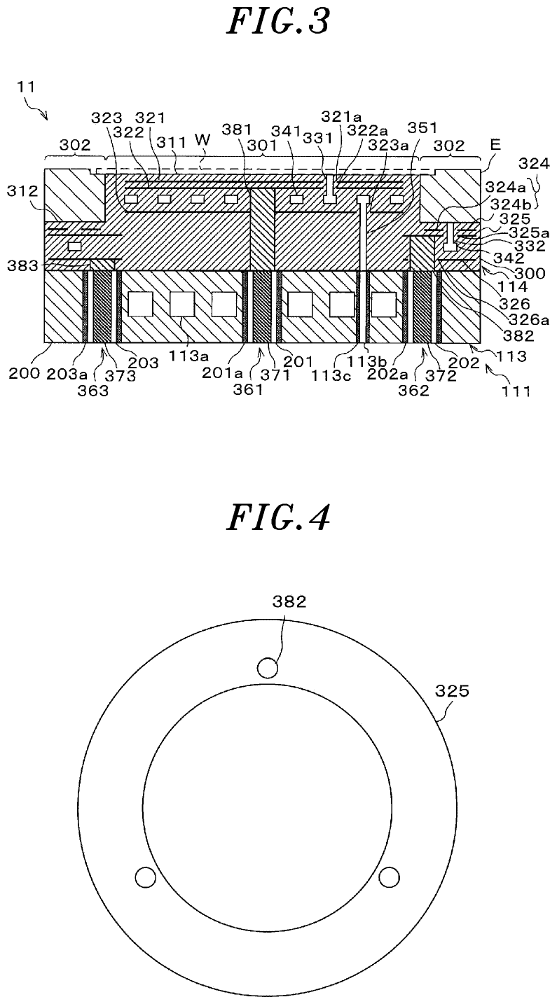

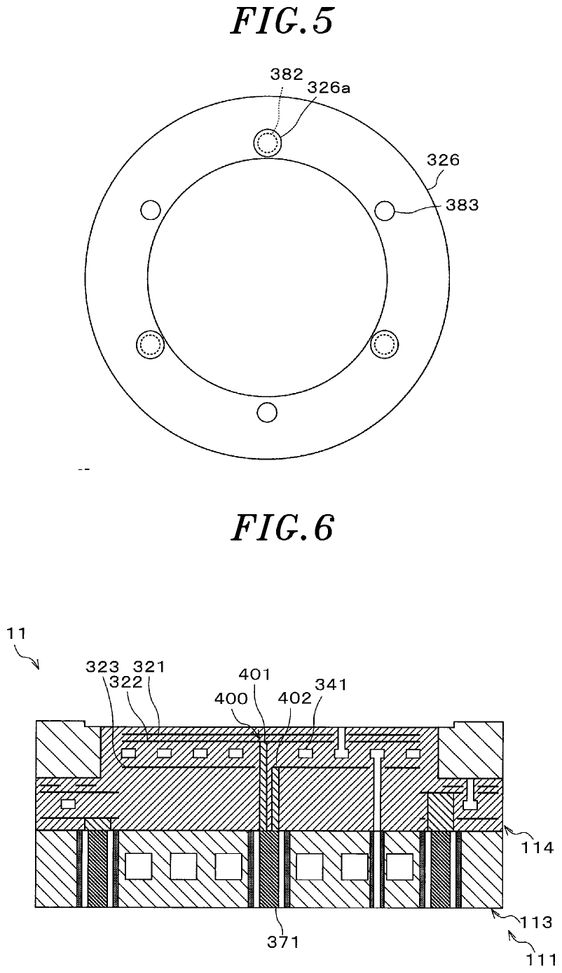

Next, the structure of the substrate support 11 will be described with reference to FIGS. 3 to 5. FIG. 3 is a cross-sectional view schematically showing a configuration example of the substrate support 11. FIG. 4 is a diagram showing the positional relationship between a fifth electrode and a second via, which will be described later. FIG. 5 is a diagram showing the positional relationship between a sixth electrode and a third via, which will be described later.

As described above, the substrate support 11 includes the main body 111 and the ring assembly 112. In the example of FIG. 3, the substrate support 11 includes an edge ring E as a ring assembly 112.

In one embodiment, the main body 111 includes the base 113 and the electrostatic chuck 114.

The base 113 has a main body 200 made of a conductive material such as AI or the like. The above-described channel 113a is formed in the main body 200. In one embodiment, the base 113 and the electrostatic chuck 114 are integrated by adhesion, for example.

A source RF signal for plasma generation can be supplied to the base 113.

The electrostatic chuck 114 is used for supporting the substrate W, specifically, for supporting the substrate W and the edge ring E. More specifically, the electrostatic chuck 114 is used for electrostatically attracting and supporting the substrate W and the edge ring E.

The electrostatic chuck 114 has the ceramic member 300 as described above. The ceramic member 300 is formed in a substantially disk shape. The ceramic member 300 may be made of ceramic such as aluminum oxide, aluminum nitride, or the like.

The ceramic member 300 has a first region 301 that is the above-described central region 111a, and a second region 302 that is the above-described annular region 111b.

The first region 301 is a region having a substantially disk shape, and has a first upper surface 311. The first region 301 is configured to support the substrate W placed on the first upper surface 311.

The second region 302 is a region having a circular ring shape in plan view, and has a second upper surface 312. The first region 301 and the second region 302 are concentric. The second region 302 is configured to support the edge ring E placed on the second upper surface 312.

In one embodiment, the first region 301 is formed to have a diameter smaller than that of the substrate W, and the first upper surface 311 is higher than the second upper surface 312. Hence, when the substrate W is placed on the first upper surface 311, the peripheral edge of the substrate W protrudes from the first region 301.

The first region 301 and the second region 302 may be formed integrally, or may be formed separately.

Further, first to third electrodes 321 to 323 are disposed in the first region 301.

The first electrode 321 is disposed in the first region 301, and a DC voltage from a DC power supply (not shown) is applied thereto. Due to the electrostatic force thus generated, the substrate W is attracted and held on the first upper surface 311. In other words, the first electrode 321 is an electrode for electrostatic attraction of the substrate W.

The first electrode 321 is formed in a circular shape in plan view.

The second electrode 322 is disposed below the first electrode 321 in the first region 301. The second electrode 322 is connected to a bias power supply (e.g., the DC power supply 32) through a first power supply line 361 to be described later, and a first bias power from the bias power supply is supplied thereto. When the first bias power is supplied to the second electrode 322, ions in the plasma are attracted toward the substrate W on the first upper surface 311. Accordingly, the process speed in the entire surface of the substrate W can be adjusted, and the etching speed in the entire surface of the substrate W can be improved in the case of etching.

The second electrode 322 is formed in a circular shape having approximately the same diameter as that of the first electrode 321 in plan view, for example.

The third electrode 323 is disposed below the second electrode 322 in the first region 301. Similarly to the second electrode 322, the third electrode 323 is connected to the bias power supply through the first power supply line 361 to be described later, and the first bias power from the bias power supply (e.g., the DC power supply 32) is supplied thereto. When the first bias power is supplied to the third electrode 323 similarly to the second electrode 322, portions between the second electrode 322 and the third electrode 323 have substantially the same potential.

The third electrode 323 is formed in a circular shape having approximately the same diameter as those of the first electrode 321 and the second electrode 322 in plan view, for example. Further, the diameters of the first to third electrodes 321 to 323 may be different from each other.

In one embodiment, the first bias power supplied to the second electrode 322 and the third electrode 323 is the bias power of the pulsed DC signal.

Further, a first gas injection hole 331, a first gas supply line 341, and a first gas inlet hole 351 are disposed in the first region 301. The first gas injection hole 331 is disposed at the upper part of the first region 301. The first gas supply line 341 is disposed between the second electrode 322 and the third electrode 323 in the first region 301. The first gas inlet hole 351 is disposed at the lower part of the first region 301. Although only one first gas injection hole 331 is illustrated in the drawing, a plurality of (e.g., thirty or more) first gas injection holes 331 are disposed. In the present embodiment, the number of the first gas inlet holes 351 is smaller than that of the first gas injection holes 331, and is one, for example. However, the number of the first gas inlet holes 351 may be the same as that of the first gas injection holes 331.

Each first gas injection hole 331 injects a heat transfer gas such as helium or the like to the gap between the backside of the substrate W placed on the first upper surface 311 and the first upper surface 311. Further, each first gas injection hole 331 has one end that is opened to the first upper surface 311 and the other end connected to the first gas supply line 341. Each first gas injection hole 331 is formed to extend in a vertical direction, and to penetrate through holes 321a and 322a formed in portions of the first electrode 321 and the second electrode 322 corresponding to the first gas injection hole 331, for example.

The first gas supply line 341 diffuses the heat transfer gas introduced from the first gas inlet hole 351 in the horizontal direction between the second electrode 322 and the third electrode 323 to be supplied to the plurality of first gas injection holes 331.

The first gas inlet hole 351 has one end in fluid connection with the first gas supply line 341 and the other end in fluid connection with a heat transfer gas supply part (not shown). The first gas inlet hole 351 introduces the heat transfer gas from the heat transfer gas supply part into the first gas supply line 341.

Further, the above-described heat transfer gas supply part may include one or more gas sources and one or more flow rate controllers. In one embodiment, the gas supply part is configured to supply a gas from the gas source to the first gas inlet hole 351 via the flow rate controller, for example. The flow controller may include, e.g., a mass flow controller or a pressure-controlled flow controller.

In one embodiment, the first gas inlet hole 351 is formed to extend in the vertical direction, and to penetrate through a hole 323a formed in a portion of the third electrode 323 corresponding to the first gas inlet hole 351, for example. Further, the lower end of the first gas inlet hole 351 opened to the bottom surface of the electrostatic chuck 114. In this case, the heat transfer gas from the above-described heat transfer gas supply part is introduced into the first gas inlet hole 351 through a gas inlet line 113b disposed in the base 113. The gas inlet line 113b is formed to extend in the vertical direction and to penetrate through the base 113, for example. The inner circumferential wall of the gas inlet line 113b is covered with an insulating member 113c.

Further, fourth to sixth electrodes 324 to 326 are disposed in the second region 302.

The fourth electrode 324 is disposed in the second region 302, and a DC voltage from a DC power supply (not shown) is applied thereto. Due to the electrostatic force thus generated, the edge ring E is attracted and held on the second upper surface 312. In other words, the fourth electrode 324 is an electrode for electrostatic attraction of the edge ring E.

The fourth electrode 324 is formed in an annular shape in plan view, and more specifically, in a circular ring shape in plan view.

Further, in the present embodiment, the fourth electrode 324 is of a bipolar type including a pair of electrodes 324a and 324b, for example. In this case, each of the electrodes 324a and 324b is formed in a circular ring shape in plan view. However, the fourth electrode 324 may be of a unipolar type.

The fifth electrode 325 is disposed below the fourth electrode 324 in the second region 302. The fifth electrode 325 is connected to the bias power supply (e.g., the DC power supply 32) through a second power supply line 362 to be described later, and a second bias power from the bias power supply is supplied thereto. By adjusting the magnitude of the second bias power supplied to the second electrode 322, the shape of the ion sheath above the edge ring E on the second upper surface 312 can be adjusted.

The fifth electrode 325 is formed in an annular shape in plan view, and more specifically formed in a circular ring shape in plan view. Further, the inner diameter of the fifth electrode 325 is substantially the same as the inner diameter of the fourth electrode 324 (specifically, the inner diameter of the inner electrode 324a), and the outer diameter of the fifth electrode 325 is substantially the same as the outer diameter of the fourth electrode 324 (specifically, the outer diameter of the outer electrode 324b).

The sixth electrode 326 is disposed below the fifth electrode 325 in the second region 302. The sixth electrode 326 is connected to the bias power supply (e.g., the DC power supply 32) through a third power supply line 363 to be described later, and a third bias power from the bias power supply is supplied thereto. When the second bias power is supplied to the fifth electrode 325 and the third bias power whose magnitude is substantially the same as that of the second bias power is supplied to the sixth electrode 326, portions between the fifth electrode 325 and the sixth electrode 326 have substantially the same potential.

The sixth electrode 326 is formed in a circular ring shape having substantially the same diameter as that of the fifth electrode 325 in plan view. Further, the inner diameters and the outer diameters of the fourth to sixth electrodes 324 to 326 may be different from each other.

In one embodiment, the second bias power supplied to the fifth electrode 325 and the third bias power supplied to the sixth electrode 326 are the bias powers of the pulsed DC signal.

Further, the first bias power supplied to the second electrode 322 and the third electrode 323, the second bias power supplied to the fifth electrode 325, and the third bias power supplied to the sixth electrode 326 are independently controlled. Further, the second bias power supplied to the fifth electrode 325 and the third bias power supplied to the sixth electrode 326 may be independently controlled.

Further, a second gas injection hole 332 and a second gas supply line 342 are disposed in the second region 302. The second gas injection hole 332 is disposed at the upper part of the second region 302, and the second gas supply line 342 is disposed between the fifth electrode 325 and the sixth electrode 326 in the second region 302. Although only one second gas injection hole 332 is illustrated in the drawing, a plurality of (for example, ten or more) second gas injection holes 332 are disposed along a circumferential direction with respect to the central axis of the electrostatic chuck 114.

Each second gas injection hole 332 injects a heat transfer gas such as helium or the like to the gas between the backside of the edge ring E placed on the second upper surface 312 and the second upper surface 312. Further, each second gas injection hole 332 has one end opened to the second upper surface 312 and the other end connected to the second gas supply line 342. Each second gas injection hole 332 is formed to extend in the vertical direction, and to penetrate through a hole 325a formed at a portion of the fifth electrode 325 corresponding to each second gas injection hole 332 while passing through the gap between the electrode 324a and the electrode 324b, for example.

The second gas supply line 342 diffuses the heat transfer gas introduced from the heat transfer gas supply section (not shown) in the horizontal direction between the fifth electrode 325 and the sixth electrode 326 to be supplied to the plurality of second gas injection hole 332.

Further, the above-described heat transfer gas supply part may include one or more gas sources and one or more flow rate controllers. In one embodiment, the gas supply part is configured to supply a gas from the gas source to the first gas inlet hole 351 via the flow rate controller, for example. The flow controller may include, e.g., a mass flow controller or a pressure-controlled flow controller.

Further, the heat transfer gas is supplied from the heat transfer gas supply part to the second gas supply line 342 through, e.g., a gas inlet hole formed in the second region 302 similarly to the first gas inlet hole 351, and a gas inlet line formed in the base 113 similarly to the gas inlet line 113b.

Further, the substrate support 11 has a first power supply line 361 that is in electrical contact with the second electrode 322 and the third electrode 323 and supplies the first bias power to the second electrode 322 and the third electrode 323. The first power supply line 361 has a first power supply terminal 371 and a first via 381 serving as a first internal power supply line.

The first power supply terminal 371 is disposed in the base 113, and supplies the first bias power from the bias power supply (e.g., the DC power supply 32) to the first via 381. The first power supply terminal 371 is formed to extend in the vertical direction, and to penetrate through the base 113, for example. In this case, the first power supply terminal 371 is disposed in a through-hole 201 penetrating through the main body 200 of the base 113 in the vertical direction. The inner circumferential wall of the through-hole 201 is covered with an insulating member 201a.

The first via 381 is in electrical contact with the first power supply terminal 371, and is disposed in the first region 301 of the electrostatic chuck 114. The first via 381 is formed to extend downward from the central portion of the second electrode 322 and reach the bottom surface of the electrostatic chuck 114. In this case, the upper end of the first via 381 is electrically and physically connected to the central portion of the second electrode 322. Further, the first via 381 penetrates through the central portion of the third electrode 323, and the first via 381 and the third electrode 323 are electrically and physically connected at the penetrating portion.

Further, the substrate support 11 has the second power supply line 362 that is in electrical contact with the fifth electrode 325 and supplies the second bias power to the fifth electrode 325. The second power supply line 362 has a second power supply terminal 372 and a second via 382 as a second internal power supply line. For example, as shown in FIG. 4, three or more second vias 382 are arranged at approximately equal intervals along the circumferential direction with respect to the center of the fifth electrode 325, that is, the central axis of the electrostatic chuck 114. Further, the second power supply terminal 372 is provided for each second via 382.

As shown in FIG. 3, each second power supply terminal 372 is disposed in the base 113, and supplies the second bias power from the bias power supply (e.g., the DC power supply 32) to the second via 382. Each second power supply terminal 372 is formed to extend in the vertical direction, and to penetrate through the base 113, for example. In this case, each second power supply terminal 372 is disposed in a through-hole 202 penetrating through the main body 200 of the base 113 in the vertical direction. The inner circumferential wall of the through-hole 202 is covered with an insulating member 202a.

Each second via 382 is in electrical contact with the second power supply terminal 372, and is disposed in the second region 302 of the electrostatic chuck 114. Each second via 382 is formed to extend downward from the fifth electrode 325, penetrate through a hole 326a formed in a portion of the sixth electrode 326 corresponding to each second via 382, and reach the bottom surface of the electrostatic chuck 114, for example. In this case, the upper end of the second via 382 is electrically and physically connected to the fifth electrode 325. Further, the second via 382 and the sixth electrode 326 are not physically connected and are electrically insulated from each other.

Further, the substrate support 11 has a third power supply line 363 that is in electrical contact with the sixth electrode 326 and supplies the third bias power to the sixth electrode 326. The third power supply line 363 has a third power supply terminal 373 and a third via 383 as a third internal power supply line. For example, as shown in FIG. 5, three or more third vias 383 are arranged at approximately equal intervals along the circumferential direction with respect to the center of the sixth electrode 326, that is, the central axis of the electrostatic chuck 114. Further, in the case where three or more third vias 383 and three or more second vias 382, which are the same in number, are arranged at equal intervals along the circumferential direction, the third vias 383 and the second vias 382 may be arranged alternately.

Each third power supply terminal 373 is disposed in the base 113, and supplies a third bias power from a bias power supply (not shown) to the third via 383. Each third power supply terminal 373 is formed to extend in the vertical direction, and to penetrate through the base 113, for example. In this case, each third power supply terminal 373 is disposed in a through-hole 203 penetrating through the main body 200 of the base 113 in the vertical direction. The inner circumferential wall of the through-hole 203 is covered with an insulating member 203a.

Each third via 383 is in electrical contact with the third power supply terminal 373, and is disposed in the second region 302 of the electrostatic chuck 114. Each third via 383 is formed to extend downward from the sixth electrode 326 and reach the bottom surface of the electrostatic chuck 114, for example. In this case, the upper end of the third via 383 is electrically and physically connected to the sixth electrode 326.

Each of the second via 382 and the third via 383 is formed in a columnar shape (e.g., a cylindrical shape) extending in the vertical direction, for example. The second via 382 and the third via 383 are made of, e.g., a conductive material such as conductive ceramic or metal.

### Main Effects

Next, the main effects of the substrate support 11 according to the present embodiment will be described.

Recently, it is required to perform plasma processing, such as deep hole etching represented by a 3D NAND flash memory, with a high output. In the case of performing processing with a high output, the temperature of the substrate W becomes high, so heat a transfer gas is supplied to the gap between the backside of the substrate W and the substrate support to efficiently cool the substrate W. Further, if the temperature of the substrate W becomes non-uniform in the surface of the substrate, the yield of the product is affected. Therefore, in order to obtain the in-plane uniformity of the temperature of the substrate W, a plurality of heat transfer gas injection holes are formed in the surface of the substrate support 11 on which the substrate W is placed. If the plurality of injection holes are formed, a gas diffusion channel for diffusing a heat transfer gas in the horizontal direction, i.e., in a direction parallel to the surface of the substrate, to be supplied to the injection holes may be used, similarly to the first gas supply line 341 of the present embodiment. The heat transfer gas can be distributed more efficiently in the case of using the above-described gas diffusion channel than in the case of providing a supply channel for each injection hole.

It is preferable that the gas diffusion channel is disposed in the electrostatic chuck rather than in the base. This is because if the gas diffusion channel is disposed in the base, the volume of the gas channel in the base increases, and a large amount of an insulating material that covers the inner wall of the channel to suppress occurrence of abnormal discharge in the gas channel is required, which result in a high cost. Further, if the gas diffusion channel is disposed in the base, a degree of freedom in designing a temperature control coolant channel in the base is affected, and it is difficult to obtain desired temperature distribution on the substrate placing surface of the base.

In other words, the structure in which the gas diffusion channel is disposed in the electrostatic chuck is expected to improve the diffusion rate of the heat transfer gas, increase a degree of freedom in designing the coolant channel in the base, and reduce a cost.

However, in the case of simply providing the gas diffusion channel in the electrostatic chuck, a potential difference occurs between the substrate and the base when the RF power for plasma generation is supplied to the base. Accordingly, a potential difference also occurs in the gas diffusion channel, and abnormal discharge may occur in the gas diffusion channel.

Further, in order to improve the processing speed such as an etching rate or the like, it is preferable to provide a bias electrode to which a bias power for attracting ions to the electrostatic chuck is supplied in the electrostatic chuck, similarly to the second electrode 322 of the substrate support 11 according to the embodiment.

Therefore, in the substrate support 11 according to the present embodiment, the first gas supply line 341 that is the above-described gas diffusion channel is disposed below the second electrode 322 to which the first bias power for ion attraction is supplied in the electrostatic chuck 114. Further, in the substrate support 11 according to the present embodiment, the third electrode 323 to which the first bias power is supplied is disposed further below the first gas supply line 341, similarly to the second electrode 322. In other words, in the substrate support 11, the first gas supply line 341 is disposed between the second electrode 322 and the third electrode 323 to which the first bias power is supplied. Therefore, the potential difference that occurs in the first gas supply line 341 is small, which makes it possible to suppress occurrence of abnormal discharge in the first gas supply line 341.

Further, in the present embodiment, both the second electrode 322 and the third electrode 323 are provided, so that it is possible to suppress the electric field from reaching a position below the second electrode 322 from the hole 322a for the first gas injection hole 331 of the second electrode 322, compared to when only the second electrode 322 is provided. Therefore, it is possible to suppress occurrence of a potential difference in the first gas supply line 341 and the vicinity of the position below the hole 322a of the second electrode 322 in the first gas injection hole 331, and also possible to suppress occurrence of abnormal discharge.

In other words, in accordance with the present embodiment, as described above, it is possible to achieve both the structure in which the gas diffusion channel is disposed in the electrostatic chuck to improve the diffusion rate of the heat transfer gas, increase a degree of freedom in designing the coolant channel in the base, and reduce a cost, and the structure in which the bias electrode is disposed in the electrostatic chuck to improve the processing speed.

Further, in the substrate support 11 according to the present embodiment, the occurrence of abnormal discharge in the second gas supply line 342 that is the gas diffusion channel for the edge ring E can be suppressed for the same reason as in the first gas supply line 341.

In the present embodiment, the first via 381 is connected to the central portion of the second electrode 322 and the central portion of the third electrode 323. Accordingly, the in-plane uniformity of the potential of each of the second electrode 322 and the third electrode 323 can be obtained, compared to when the first via 381 is connected to only one position of the peripheral portion of each of the second electrode 322 and the third electrode 323.

Further, in the present embodiment, three or more second vias 382 and three or more third vias 383 are arranged at approximately equal intervals along the circumferential direction. Accordingly, the potential of each of the fifth electrode 325 and the sixth electrode 326 can become more uniform in the circumferential direction, compared to when only one second via 382 and only one third via 383 are connected.

### Modification

FIG. 6 is a diagram showing another example of the first internal power supply line.

In the above example, the first via 381 serves as a first internal power supply line that is in electrical contact with the first power supply terminal 371 and disposed in the first region 301 of the electrostatic chuck 114.

In the example of FIG. 6, the electrostatic chuck 114 includes a first internal power supply line 400 having a first distribution power supply line 401 and a second distribution power supply line 402.

The first distribution power supply line 401 is in electrically contact with the second electrode 322 but is not in electrical contact with the third electrode 323.

The second distribution power supply line 402 is in electrical contact with the third electrode 323 but is not in electrical contact with the second electrode 322.

Further, the first distribution power supply line 401 and the second distribution power supply line 402 are in electrical contact with the first power supply terminal 371.

In this configuration, the first distribution power supply line 401 and the second distribution power supply line 402 are made of different materials, so that the first distribution power supply line 401 and the second distribution power supply line 402 may have different electrical resistance values, and the potential difference between the second electrode 322 and the third electrode 323 may be obtained while avoiding occurrence of abnormal discharge. Accordingly, the influence of the presence of the third electrode 323 on the etching characteristics can be adjusted. In other words, in this configuration, it is possible to suppress the occurrence of a potential difference in the first gas supply line 341 while ensuring desired etching characteristics.

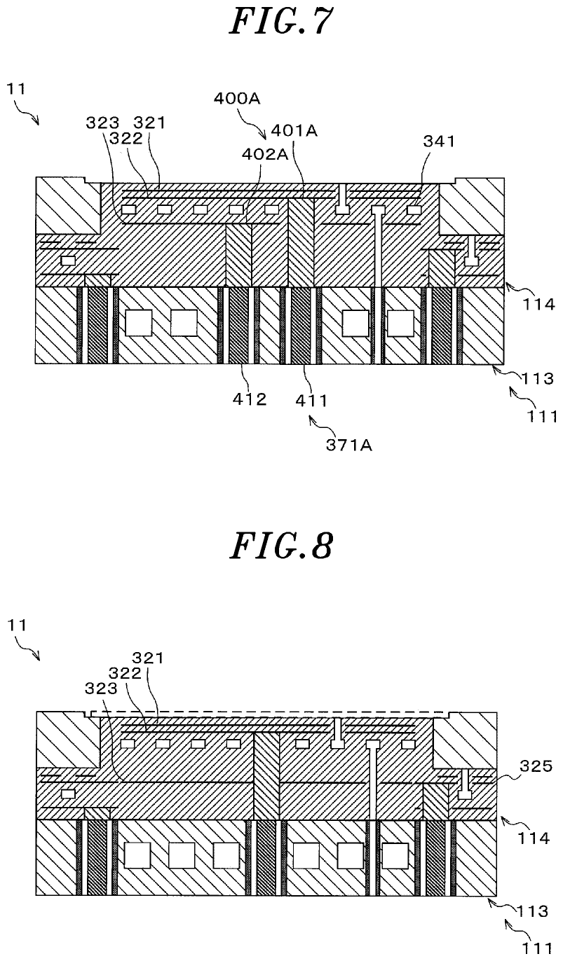

FIG. 7 is a diagram showing another example of the first power supply terminal.

In the example of FIG. 7, similarly to the example of FIG. 7, the electrostatic chuck 114 includes a first internal power supply line 400A having a first distribution power supply line 401A in electrical contact with the second electrode 322 and a second distribution power supply line 402A in electrical contact with the third electrode 323. However, unlike the example of FIG. 6, a first power supply terminal 371A in electrical contact with the first internal power supply line 400A includes a first distribution power supply terminal 411 in electrical contact with the first distribution power supply line 401A, and a second distribution power supply terminal 412 in electrical contact with the second distribution power supply line 402A.

The first power distribution power supply terminal 411 and the second power distribution power supply terminal 412 are connected to the same power supply (e.g., the DC power supply 32), for example. In this case, similarly to the example of FIG. 6, the first distribution power supply line 401A and the second distribution power supply line 402A have different electrical resistance values, so that the potential difference between the second electrode 322 and the third electrode 323 can be obtained while avoiding occurrence of abnormal discharge.

Further, the first power distribution power supply terminal 411 and the second power distribution power supply terminal 412 may be connected to different power supplies (not shown). In this case, even if the electrical resistance values of the first distribution power supply line 401A and the second distribution power supply line 402A are not different from each other, the potential difference between the second electrode 322 and the third electrode 323 can be obtained while avoiding occurrence of abnormal discharge by applying different voltages to the first distribution power distribution terminal 411 and the second distribution power distribution terminal 412.

FIG. 8 is a diagram showing a specific example of the positional relationship between the third electrode 323 and the fifth electrode 325.

As shown in FIG. 8, the third electrode 323 and the fifth electrode 325 may be provided on the same plane. The electrostatic chuck 114 is manufactured by providing electrodes in flat plates made of an insulating material and stacking the flat plates. Since, however, the number of flat plates made of an insulating material can be reduced by providing the electrodes on the same plane as described above, the electrostatic chuck 114 can be manufactured at a low cost.

While various exemplary embodiments have been described above, various additions, omissions, substitutions, and modifications may be made without being limited to the exemplary embodiments described above. Further, elements from different embodiments can be combined to form other embodiments.

1. A substrate support comprising:
an electrostatic chuck configured to support a substrate and an edge ring; and
a base configured to support the electrostatic chuck,
wherein the electrostatic chuck includes:
a first region having a first upper surface and configured to support a substrate placed on the first upper surface;
a second region having a second upper surface, disposed around the first region, and configured to support an edge ring placed on the second upper surface;
a first electrode disposed in the first region and to which a DC voltage is applied;
a second electrode disposed below the first electrode and to which a first bias power is supplied;
a third electrode disposed below the second electrode and to which the first bias power is supplied; and
a first gas supply line disposed between the second electrode and the third electrode,
wherein the substrate support further comprises:
a first power supply line that is in electrical contact with the second electrode and the third electrode and supplies the first bias power.

2. The substrate support of claim 1, wherein the first power supply line includes:
a first power supply terminal disposed in the base; and
a first internal power supply line that is in electrical contact with the first power supply terminal and is disposed in the first region.

3. The substrate support of claim 2, wherein the first internal power supply line includes:
a first distribution power supply line that is in electrical contact with the second electrode; and
a second distribution power supply line that is in electrical contact with the third electrode,
wherein the first distribution power supply line and the second distribution power supply line are in electrical contact with the first power supply terminal.

4. The substrate support of claim 3, wherein the first power supply terminal includes:
a first distribution power supply terminal in electrical contact with the first distribution power supply line; and
a second distribution power supply terminal in electrical contact with the second distribution power supply line.

5. The substrate support of claim 4, wherein the first distribution power supply terminal and the second distribution power supply terminal are connected to the same power supply.

6. The substrate support of claim 4, wherein the first distribution power supply terminal and the second distribution power supply terminal are respectively connected to different power supplies.

7. The substrate support of claim 1, wherein the electrostatic chuck includes:
a fourth electrode disposed in the second region and to which a DC voltage is applied;
a fifth electrode disposed below the fourth electrode and to which a second bias power is supplied;
a sixth electrode disposed below the fifth electrode and to which a third bias power is supplied; and
a second gas supply line disposed between the fifth electrode and the sixth electrode,
wherein the substrate support further comprises:
a second power supply line that is in electrical contact with the fifth electrode and supplies the second bias power; and
a third power supply line that is in electrical contact with the sixth electrode and supplies the third bias power.

8. The substrate support of claim 7, wherein the second power supply line includes:
a second power supply terminal disposed in the base; and
a second internal power supply line that is in electrical contact with the second power supply terminal and is disposed in the second region.

9. The substrate support of claim 8, wherein the third power supply line includes:
a third power supply terminal disposed in the base; and
a third internal power supply line that is in electrical contact with the third power supply terminal and is disposed in the second region.

10. The substrate support of claim 9, wherein the second power supply terminal and the third power supply terminal are connected to the same power supply.

11. The substrate support of claim 9, wherein the second power supply terminal and the third power supply terminal are respectively connected to different power supplies.

12. The substrate support of claim 7, wherein the third electrode and the fifth electrode are disposed on the same plane.

13. The substrate support of claim 7, wherein the fifth electrode and the sixth electrode are formed in an annular shape in plan view.

14. The substrate support of claim 13, wherein each of the second power supply line and the third power supply line is provided at three or more locations along a circumferential direction.

15. The substrate support of claim 7, wherein the fourth electrode is an electrode for electrostatic attraction of an edge ring.

16. The substrate support of claim 7, wherein the fourth electrode is a bipolar electrode.

17. The substrate support of claim 1, wherein the first electrode is an electrode for electrostatic attraction of a substrate.

18. A plasma processing apparatus comprising:
a substrate support including an electrostatic chuck configured to support a substrate and an edge ring, and a base configured to support the electrostatic chuck; and
a plasma processing chamber in which a substrate support is disposed,
wherein the electrostatic chuck includes:
a first region having a first upper surface and configured to support a substrate placed on the first upper surface;
a second region having a second upper surface, disposed around the first region, and configured to support an edge ring placed on the second upper surface;
a first electrode disposed in the first region and to which a DC voltage is applied;
a second electrode disposed below the first electrode and to which a first bias power is supplied;
a third electrode disposed below the second electrode and to which the first bias power is supplied;
a first gas supply line disposed between the second electrode and the third electrode;
a fourth electrode disposed in the second region and to which a DC voltage is applied;
a fifth electrode disposed below the fourth electrode and to which a second bias power is supplied;
a sixth electrode disposed below the fifth electrode and to which a third bias power is supplied; and
a second gas supply line disposed between the fifth electrode and the sixth electrode,
wherein the substrate support further comprises:
a first power supply line that is in electrical contact with the second electrode and the third electrode and supplies the first bias power;
a second power supply line that is in electrical contact with the fifth electrode and supplies the second bias power; and
a third power supply line that is in electrical contact with the sixth electrode and supplies the third bias power.
